(19) United States
(12) Patent Application Publication
(10) Pub. No.: US 2025/0133771 A1
(43) Pub. Date: Apr. 24, 2025

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Yi-Syuan SIAO, Changhua city (TW); Yu Tao Sun, Taipei City (TW); Meng-Han Chou, Hsinchu (TW); Su-Hao Liu, Chiayi County (TW); Chi On Chui, Hsinchu City (TW)

(73) Assignee: Taiwan Semiconductor Manufacturing Company, Ltd., Hsinchu (TW)

(21) Appl. No.: 18/489,010

(22) Filed: Oct. 18, 2023

(51) Int. Cl. H01L 29/423; H01L 21/02; H01L 21/3205; H01L 29/06; H01L 29/66; H01L 29/786

(52) U.S. Cl. CPC H10D 30/6735; H01L 21/0245; H01L 21/02532; H01L 21/0262; H01L 21/32055; H10D 30/014; H10D 30/6757; H10D 62/121; H10D 64/017

(57) ABSTRACT

A method of forming a semiconductor device includes the following operations. A substrate is provided with a recess therein. An insulating layer is formed on a bottom of the recess. A seed layer is formed on the insulating layer. An epitaxial layer is grown in the recess from the seed layer.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (e.g., the number of interconnected devices per chip area) has generally increased while geometry size (e.g., the smallest component (or line) that can be created using a fabrication process) has decreased. This scaling down process generally provides benefits by increasing production efficiency and lowering associated costs. However, scaling down has also led to challenges that may not have been presented by previous generations at larger geometries.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, 6A, 6B, 7A, 7B, 8A, 8B, 9A, 9B, 10, 11, 12, 13A, 13B, 14, 15, 16, 17A, 17B and 17C illustrate varying views of a method of forming a semiconductor device in accordance with some embodiments.

FIGS. 18, 19, 20 and 21 illustrate cross-sectional views of a method of forming a semiconductor device in accordance with other embodiments.

FIG. 22 illustrates a flow chart of a method of forming a semiconductor device in accordance with some embodiments.

FIG. 23 illustrates a flow chart of a method of forming a semiconductor device in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure may be used to form strained features of gate stacks suitable for semiconductor devices such as gate-all-around (GAA) devices. In the disclosure, a seed layer is formed on top of an insulating layer in each source/drain recess, and an epitaxial layer is then grown by using the seed layer as a seed. The seed layer provides a good interface for epitaxially growing the epitaxial layer. Therefore, the epitaxial layer is formed without a seam or void, and the device performance and device reliability are accordingly improved.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

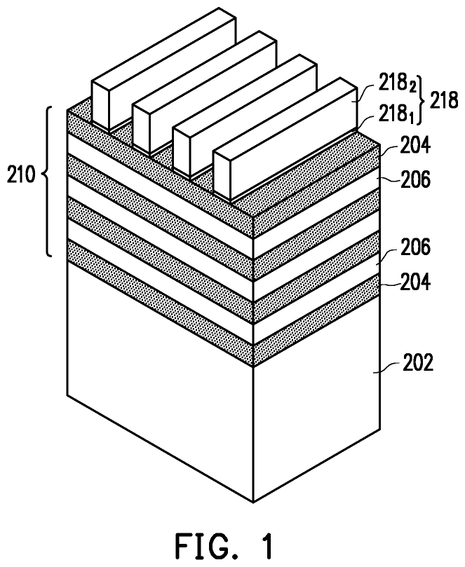

FIG. 1 to FIG. 17C illustrate varying views of a method of forming a semiconductor device in accordance with some embodiments. The semiconductor device illustrated in the following embodiments may be, for example but not limited to, a multi-gate device. As used herein, the term “multi-gate device” is used to describe a device (e.g., a semiconductor transistor) that has at least some gate material disposed on multiple sides of at least one channel of the device. In some examples, the multi-gate device may be referred to as a gate-all-around (GAA) device having a gate material disposed on four sides of at least one channel member of the device. The channel member may be referred to as “nanosheet” or “nanowire” which is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example but not limited to, a cylindrical in shape or substantially rectangular cross-section. The method is merely an example, and is not intended to limit the present disclosure beyond what is explicitly recited in the claims. Additional steps may be provided before, during, and after method, and some of the steps described can be moved, replaced, or eliminated for additional embodiments of method. Additional features may be added in the semiconductor device depicted in FIG. 1 to FIG. 17C and some of the features described below can be replaced, modified, or eliminated in other embodiments of the semiconductor device.

FIG. 1 to FIG. 5 illustrate perspective views of stages of forming a semiconductor device. Referring to FIG. 1, a substrate 202 is provided. In some embodiments, the substrate 202 includes an element semiconductor (e.g., silicon or germanium), a compound semiconductor (e.g., silicon carbide, gallium arsenic, gallium phosphide, indium phosphide, indium arsenide or indium antimonide), an alloy semiconductor (e.g., SiGe, GaAsP, AlInAs, AlGaAs, GaInAs, GaInP or GaInAsP), the like, or a combination thereof. The substrate 202 may include various doped regions (e.g., P-type or N-type doped regions) depending on design requirements.

In some embodiments, a semiconductor stack 210 is formed over the substrate 202. The semiconductor stack 210 includes first blanket layers 204 and second blanket layers 206 stacked alternately. The first blanket layers 204 and second blanket layers 206 include different materials. In some embodiments, the first blanket layers 204 are SiGe layers having a germanium percentage in the range between about 15 wt % and 80 wt %, and the second blanket layers 206 are Si layers free of germanium. In other embodiments, either of the first blanket layers 204 and second blanket layers 206 may include other materials such as germanium, a compound semiconductor (e.g., silicon carbide, gallium arsenide, gallium phosphide, indium phosphide, indium arsenide or indium antimonide), an alloy semiconductor (e.g., SiGe, GaAsP, AlInAs, AlGaAs, InGaAs, GaInP or GaInAsP), the like, or a combination thereof.

The first blanket layers 204 and the second blanket layers 206 have materials with different etching selectivities. In some embodiments, the first blanket layers 204 and the second blanket layers 206 are formed by an epitaxial growth process. In some embodiments, the first blanket layers 204 are epitaxial SiGe layers, and the second blanket layers 206 are epitaxial Si layers. In other embodiments, the first blanket layers 204 and the second blanket layers 206 are formed by a suitable deposition. In some embodiments, the first blanket layers 204 are poly-SiGe layers, and the second blanket layers 206 are poly-Si layers.

In the illustrated embodiment, the bottom layer and the top layer of the semiconductor stack 210 are SiGe layers. However, the disclosure is not limited thereto. In other embodiments (not shown), the bottom layer of the semiconductor stack 210 is a Si layer and the top layer of the semiconductor stack 210 is a SiGe layer. It is noted that four layers of first blanket layers 204 and three layers of second blanket layers 206 are illustrated in FIG. 1, which is for illustrative purposes only and not intended to be limiting beyond what is specifically shown in the drawings. Specifically, any number of epitaxial layers may be formed in the semiconductor stack 210; the number of layers depending on the desired number of channel regions for the semiconductor device.

In some embodiments, each of the first blanket layers 204 and the second blanket layers 206 has a thickness ranging from about 2 nm to about 30 nm. As described in more detail below, the second blanket layer 206 may serve as channel region(s) for a subsequently formed multi-gate device and its thickness chosen based on device performance considerations. The first blanket layer 204 may be configured to define a gap between adjacent channel region(s) for a subsequently formed multi-gate device and its thickness chosen based on device performance considerations.

Still referring to FIG. 1, mask strips 218 are formed over the semiconductor stack 210. In some embodiments, the mask strips 218 are formed by depositing a mask layer on the semiconductor stack 210 and patterning the mask layer by photolithography and etching processes. The mask layer may include a dielectric material, such as silicon oxide, silicon nitride, SiON, SiC, SiCN, SiOCN, the like, or a combination thereof. In some embodiments, each of the mask strips 218 includes a first mask pattern 218₁ (e.g., silicon oxide layer) and a second mask pattern 218₂ (e.g., silicon nitride layer) over the first mask pattern 218₁.

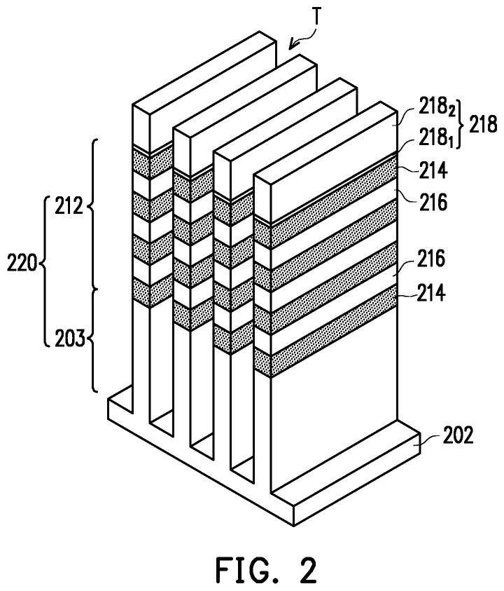

Referring to FIG. 2, the semiconductor stack 210 and the substrate 202 are patterned by using the mask strips 218 as a mask, so as to form semiconductor strips 220 separated by trenches T. The patterning process includes an etching process, such as a dry etching or the like. As shown in FIG. 2, the trenches T extend into the substrate 202, and have lengthwise directions parallel to each other. Herein, the semiconductor strips 212 are referred to as “hybrid fins” in some examples. In some embodiments, each of the semiconductor strips 220 includes a fin 203 protruding from the substrate 202, and a nanosheet stack 212 on the fin 203. In some embodiments, the nanosheet stack 212 includes first nanosheets 214 and second nanosheets 216 stacked alternately. The nanosheets are referred to as “nanowires” or “semiconductor nanosheets” in some examples. In some embodiments, the first nanosheets are referred to as “sacrificial nanosheets”, “dummy nanosheets” or “dummy portions” which will be subsequently removed and replaced by a metal gate structure, and the second nanosheets are referred to as “channel nanosheets”, “channel members” or “channel portions” which will serve as semiconductor channels. Although only four semiconductor strips 220 are illustrated in FIG. 2, the embodiments of the present disclosure are not limited thereto. In other embodiments, the number of the semiconductor strips 220 may be adjusted as needed. The adjacent semiconductor strips 220 may have the same width or different widths.

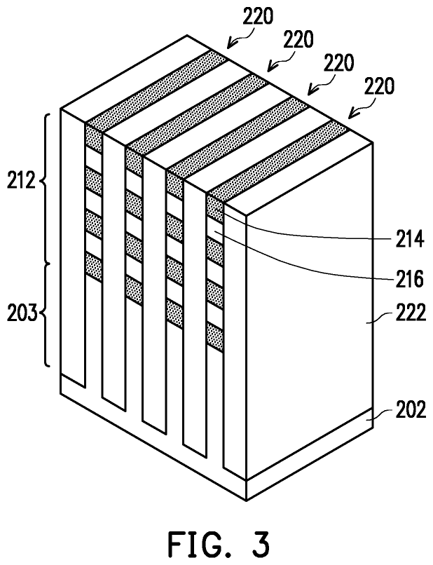

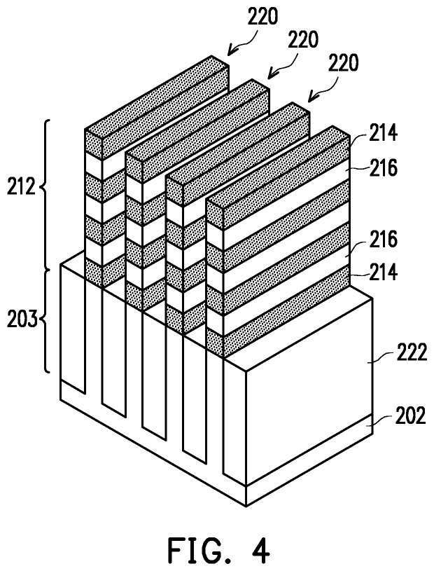

Referring to FIG. 3 and FIG. 4, insulating regions 222 are formed in the trenches T between the semiconductor strips 220. In some embodiments, an insulating material is formed on the substrate 202, covering the semiconductor strips 220 and filling up the trenches T. The insulating regions 222 are formed by depositing an insulating material over the mask strips 218 and performing a planarization process to remove a portion of the insulating material and the mask strips 218, until the semiconductor strips 220 are exposed. In some embodiments, as shown in FIG. 3, the top surfaces of the semiconductor strips 220 are substantially coplanar with the top surfaces of the insulating regions 222. In some embodiments, the insulating regions 222 may have a flat surface, a convex surface, a concave surface (such as dishing), or a combination thereof. In some embodiments, a height difference between the top surfaces of the semiconductor strips 220 and the top surfaces of the insulating regions 222 ranges from about 30 nm to about 100 nm. The insulating regions 222 are referred to as “isolation strips” or “shallow trench isolation (STI) regions” in some examples.

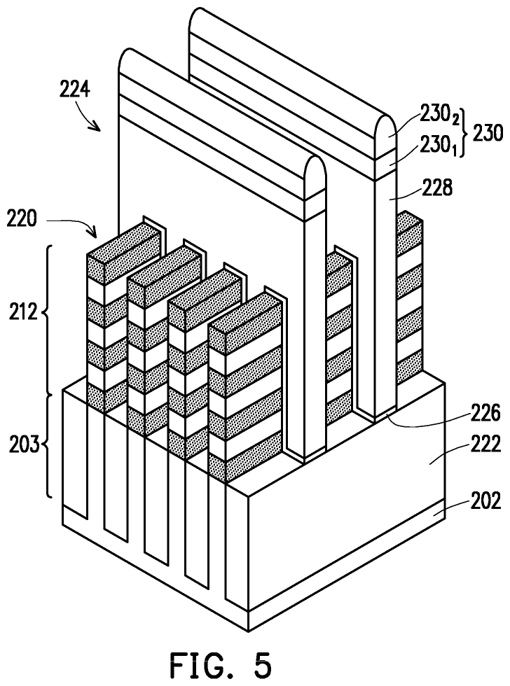

Referring to FIG. 5, at least two dummy gate stacks 224 are formed across portions of the nanosheet stacks 212 and portions of the insulating regions 222. The dummy gate stacks 224 may extend along a direction different from (e.g., perpendicular to) the extending direction of the nanosheet stacks 212. The dummy gate stacks 224 define the channel regions of the GAA devices. Each dummy gate stack 224 includes a dummy gate dielectric layer 226 and a dummy gate electrode layer 228 over the dummy gate dielectric layer 226. In some embodiments, a dummy gate dielectric material and a dummy gate electrode material are blanket-formed over the semiconductor strips 220. The dummy gate dielectric material and the dummy gate electrode material are deposited using a suitable deposition process. A mask layer 230 is formed over the dummy gate electrode material. The mask layer 230 may include a dielectric material, such as silicon oxide, silicon nitride, SiON, SiC, SiCN, SiOCN, the like, or a combination thereof. In some embodiments, the mask layer 230 includes a first mask layer 2301 (e.g., silicon oxide layer) and a second mask layer 2302 (e.g., silicon nitride layer) over the first mask layer 2301. Thereafter, the dummy gate dielectric material and dummy gate electrode material are patterned into the dummy gate stacks 224 by using the mask layer 230 as a mask. The mask layer 230 is regarded as part of the dummy gate stack 224 in some examples.

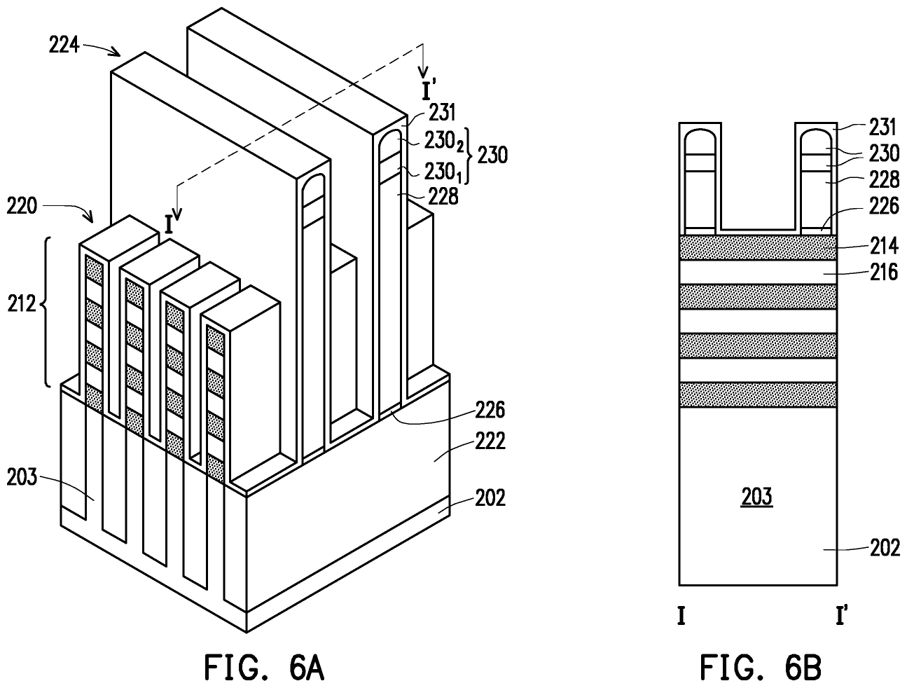

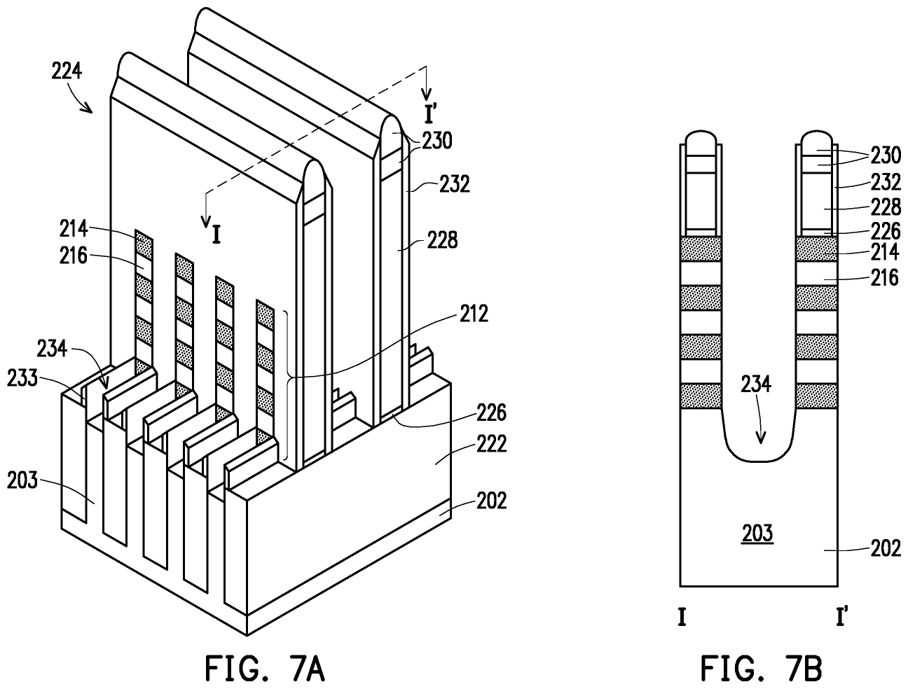

Referring to FIG. 6A, FIG. 6B, FIG. 7A and FIG. 7B, spacers 232 are formed on sidewalls of the dummy gate stacks 224 and sidewalls of the nanosheet stacks 212 by depositing a spacer material 231 and followed by an anisotropic etching. In some embodiments, the spacers 232 include a dielectric material, such as silicon oxide, silicon nitride, SiON, SiC, SiCN, SiOCN, or a combination thereof. Other materials such as a low-k material may be applicable. The low-k material has a dielectric constant less than 3.9, less than 3, less than 2.5, or even less. Although the spacers 232 illustrated in FIG. 7A and FIG. 7B have a single-layer structure, the embodiments of the present disclosure are not limited thereto. In other embodiments, the spacers 232 may have a multi-layer structure. For example, the spacers 232 may include a silicon oxide layer and a silicon nitride layer on the silicon oxide layer.

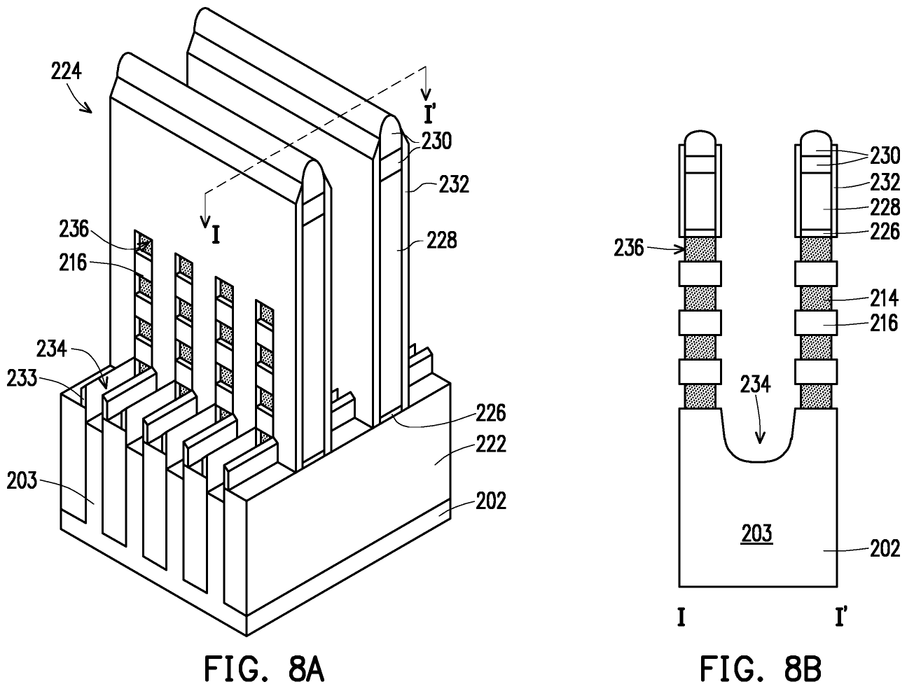

Upon the spacer forming operation, the dummy gate stacks 224 and the spacers 232 cover portions of the nanosheet stacks 212, and expose the portions of the nanosheet stacks 212. As shown in FIG. 8A and FIG. 8B, the exposed portions of the nanosheet stacks 212 are removed and the underlying fins 203 are recessed to form recesses 234. In other words, the end portions of the nanosheet stacks 212 are entirely removed and portions of the fins 203 are further removed. The recesses 234 are referred to as “source/drain (S/D) recesses” in some examples. In some embodiments, the end portions of the nanosheet stacks 212 may be removed by an anisotropic etching process, an isotropic etching process, or a combination thereof. In some embodiments, the top surfaces of the recesses 234 are lower than the top surfaces of the insulating regions 222. In some embodiments, the spacers 232 on the nanosheet stacks 212 are partially removed during the recess forming operation, and the remaining spacers 233 are left standing over and aligned to the edges of insulating regions 222, with the recesses 234 formed therebetween, as shown in FIG. 7A. In some embodiments, the method of forming the recesses 234 includes performing a suitable etching process, such as a dry etching process, a wet etching process, or an RIE process.

Referring to FIG. 8A and FIG. 8B, portions of the first nanosheets 214 are laterally recessed. In some embodiments, the portions of the first nanosheets 214 exposed by the recesses 234 are removed, and thus, cavities 236 are respectively formed between the second nanosheets 216. In some embodiments, the first nanosheets 214 are laterally recessed by a wet etching, a dry etching, or a combination thereof. For example, the first nanosheets 214 may be selectively etched by using a wet etchant. In other embodiments, before laterally recessing the portions of the first nanosheets 214, the end portions of the first nanosheets 214 exposed by the recesses 234 may be selectively oxidized, so as to increase the etching selectivity between the first and second nanosheets 214 and 216. In other embodiments, the oxidation process may be performed by exposing to a wet oxidation process, a dry oxidation process, or a combination thereof.

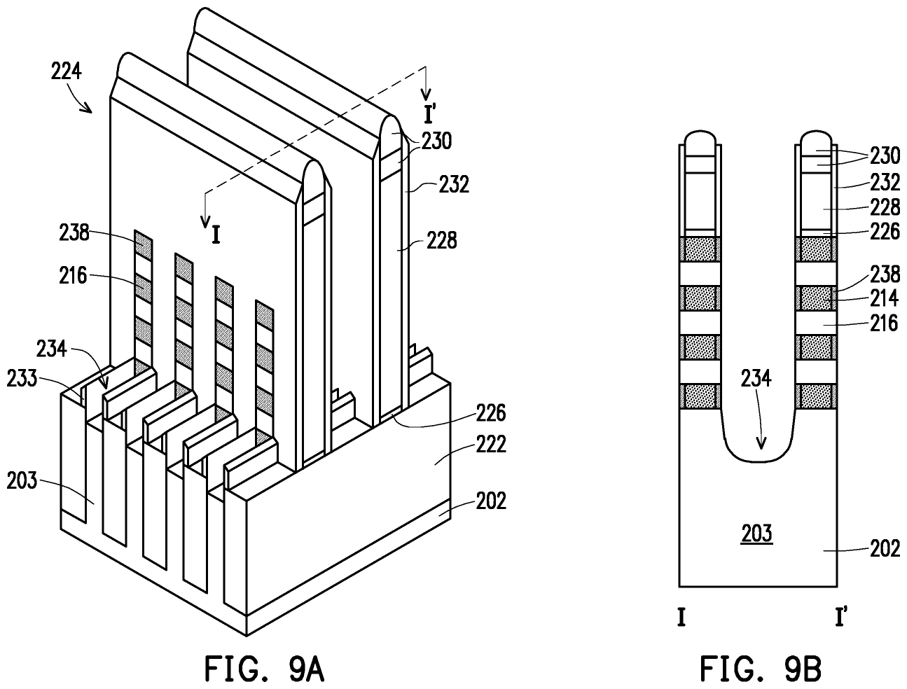

Referring to FIG. 8A, FIG. 8B, FIG. 9A and FIG. 9B, inner spacers 238 are formed in the cavities 236. In some embodiments, an inner spacer material is formed on the substrate 202. In some embodiments, the inner spacer material conformally covers the recesses 234 and the spacers 232 on the dummy gate stacks 224, and further fills in the cavities 236 to reduce the size of the cavities 236 or completely fill in the cavities 236. In some embodiments, the inner spacer material includes silicon oxide, silicon nitride, silicon carbide, silicon carbide nitride, silicon oxide carbide, silicon carbide oxynitride, and/or other suitable dielectric materials, and may be formed by CVD, PVD, ALD or a suitable method. Other materials such as a low-k material may be applicable. The low-k material has a dielectric constant less than 3.9, less than 3, less than 2.5, or even less. Thereafter, the inner spacer material is partially removed to form inner spacers 238 in the cavities 236. In some embodiments, the inner spacer material layer is partially removed by a plasma dry etching or a suitable method. Generally, the plasma dry etching etches a layer in wide and flat areas faster than a layer in concave (e.g., holes, grooves and/or slits) portions. Thus, the remaining inner spacer material forms the inner spacers 238 inside the cavities 236.

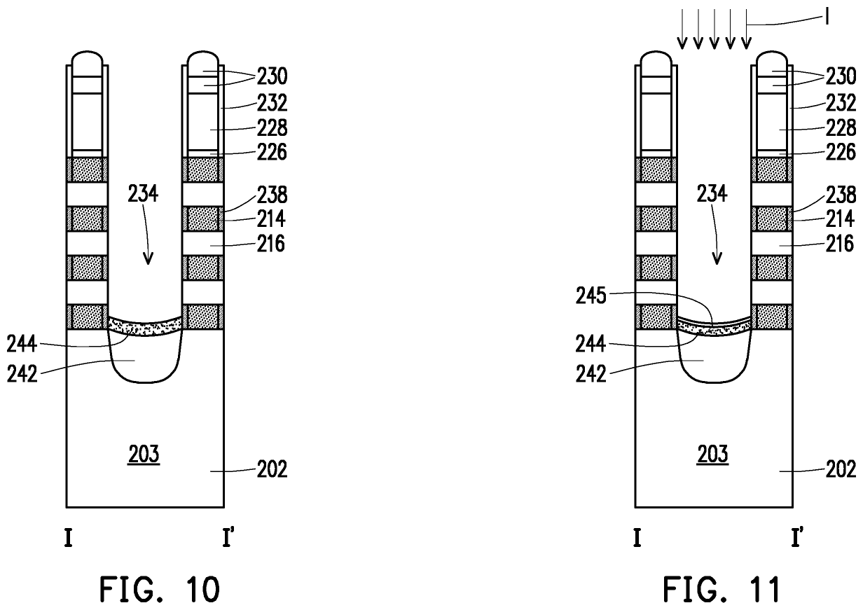

Referring to FIG. 10, liner layers 242 are formed in bottoms of the recesses 234, respectively. In some embodiments, the liner layers 242 include Si, Ge, SiGe, the like, or a combination thereof. In some embodiments, the liner layers 242 are formed by an epitaxial growth process and are grown from the bottoms of the recesses 234.

Thereafter, insulating layers 244 are formed in the recesses 234 over the liner layers 242, respectively. The insulating layers 244 are configured to prevent bottom parasitic transistor leakage current while also reducing parasitic capacitance (e.g., effective capacitance C_{eff}). The insulating layers 244 are referred to as “flexible-bottom insulators (FBI) in some examples. In some embodiments, an insulating material is formed over the substrate 202, covering the sidewalls and bottoms of the recesses 234. In some embodiments, the top surface of the insulating layer 244 in reach recess 234 is lower than the bottom surface of the bottommost second nanosheet 216. The top surface of the insulating layer 244 may be recessed or planar. In some embodiments, the insulating material includes silicon oxide, silicon nitride, SiON, SiC, SiCN, SiOCN, metal oxide, metal nitride, the like, or a combination thereof. In some embodiments, the insulating material is formed thicker on the bottoms of the recesses 234 while thinner on the sidewalls of the recesses 234 by adjusting parameters of a deposition process such as CVD, PECVD, ALD or PEALD. Thereafter, an etching back process is performed to the insulating material. The etching back process completely removes thinner portions of the insulating material on the sidewalls of the recesses 234, and the remaining portions of the insulating material on the bottoms of the recesses 234 form the insulating layers 244.

Referring to FIG. 11, an implantation process I is performed to the insulating layers 244 to form seed layers 245 on tops of the insulating layers 244, respectively. Specifically, the implantation process I is performed to transform a surface portion of each insulating layer 244 into a seed layer 245. In some embodiments, the implanted species of the implantation process I includes a seed species. For example, the seed species includes Si, SiFₓ, Ge, GeFₓ or a combination thereof, wherein x is greater than zero, and the implanted concentration ranges from about 1E21 to 1E23 atom/cm³. In some embodiments, the implanted species further includes a dopant species, which has a conductivity type the same as that of the subsequently formed epitaxial layer. For example, the dopant species includes B, P As, C, Ge or a combination thereof, and the dopant concentration ranges from about 1E20 to 1E22 atom/cm³. In some embodiments, the implantation process I includes an implanted energy of about 0.1-2 keV, and implanted tilt angle of about 0-60 degrees, and an implanted temperature of about −100-1200° C. such as about −100-500° C. or about 150-450° C. The implantation process I is referred as a “seed implantation process”, “doping process”, “surface treatment”, “plasma treatment” or “radical treatment” in some examples. In some embodiments, the insulting layer 244 has a thickness of about 3-20 nm, and the seed layer 245 formed by implanting the surface portion of the insulating layer 244 has a thickness of about 1-15 nm.

In some embodiments, when the seed species includes Si and/or SiFₓ and the insulating layer 244 includes silicon oxide, silicon nitride, SiON, SiC, SiCN or SiOCN, the seed layer 245 transformed from the surface potion of the insulating layer 244 includes Si-rich silicon oxide, Si-rich silicon nitride, Si-rich SiON, Si-rich SiC, Si-rich SiCN or Si-rich SiOCN. Specifically, the silicon concentration of the seed layer 245 is greater than the silicon concentration of the underlying insulating layer 244. In some embodiments, the seed layer 244 has a gradient silicon concentration. Specifically, the silicon concentration of the seed layer 245 is decreased away from the top surface of the seed layer 245.

In some embodiments, when the seed species includes Ge and/or GeFₓ and the insulating layer 244 includes silicon oxide, silicon nitride, SiON, SiC, SiCN or SiOCN, the seed layer 245 transformed from the surface potion of the insulating layer 244 includes Ge-containing silicon oxide, Ge-containing silicon nitride, Ge-containing SiON, Ge-containing SiC, Ge-containing SiCN or Ge-containing SiOCN. Specifically, the seed layer 245 contains Ge, while the underlying insulating layer 244 is free of Ge. In some embodiments, the seed layer 245 has a gradient germanium concentration. Specifically, the germanium concentration of the seed layer 245 is decreased away from the top surface of the seed layer 245.

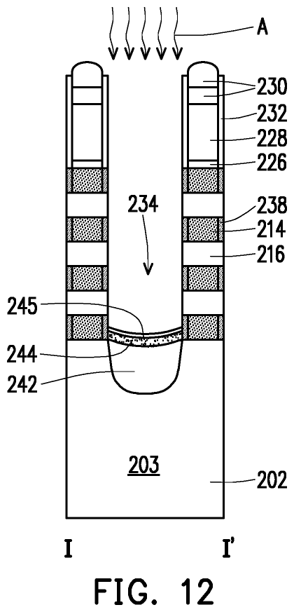

Referring to FIG. 12, an annealing process A is performed to the seed layer 245. In some embodiments, the annealing process A is performed at a temperature from about 300° C. to 1200° C. for about 10⁻³ to 10³ seconds. The annealing process A is referred to as a “post-annealing process” in some examples. The annealing process A may repair the implant damage caused by the implantation process I. In some embodiments, the annealing process A includes sub/millisecond annealing, RTA spike/soak, furnace, microwave, melting laser (e.g., nanosecond annealing) or the like. The annealing process A is optional and may be omitted in some examples. For example, when the implantation process I is performed at a high temperature from about 300° C. to 1200° C. (e.g., hot silicon implantation or hot germanium implantation), an annealing process may not be required.

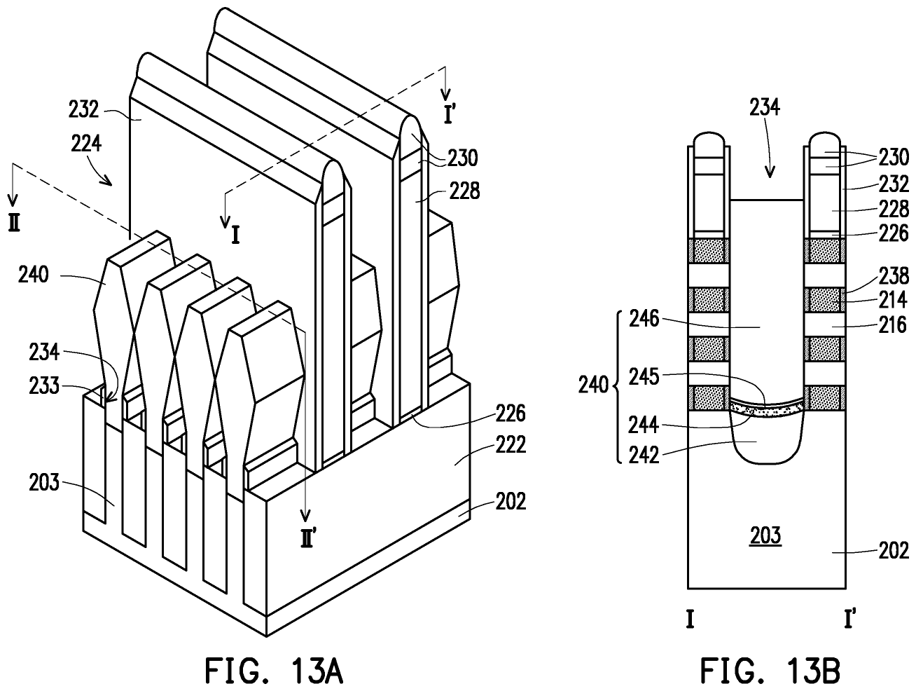

Referring to FIG. 13A and FIG. 13B, epitaxial layers 246 are epitaxially grown in the recesses 234 from the seed layers 245. In some embodiments, the seed layers 245 are beneficial for forming the epitaxial layers 246 in the recesses 234, because the seed layers 245 provide better interfaces than the insulating layers 244 for epitaxially growing the epitaxial layers 246. Therefore, the epitaxial layers 246 are void-free or seam-free epitaxial features. In some embodiments, the epitaxial layers 246 include SiP, SiAs, SiSb, SiP+SiAs, SiP+SiSb, SiP+SiAs+SiSb or the like, each of which may be doped with C, for an N-type device. In some embodiments, the epitaxial layers 246 include Si: B, Si: Ga, Si: In, SiGe, SiGe: B, SiGe: Ga, SiGe: In or the like, for a P-type device. In some embodiments, when the epitaxial layers 246 are provided for an N-type device, the seed layers 245 may include Si and/or SiFₓ, optionally doped with an N-type dopant. In some embodiments, when the epitaxial layers 246 are provided for a P-type device, the seed layers 245 may include Ge and/or GeFₓ, optionally doped with a P-type dopant. In some embodiments, the P-type or N-type dopant concentration ranges from about 1E20 to 1E22 atom/cm³.

In this embodiment, the seed layer 245 is formed on the bottom of each recess 234, so the epitaxial material is epitaxially grown from the seed layer 245 on the bottom of the recess 234 and from the silicon nanosheets 216 on the sidewall of the recess 124, and is finally merged to a void-free or seam-free epitaxial feature.

In some embodiments, a liner layer 242, an insulating layer 244, a seed layer 245 and an epitaxial layer 246 in each recess 234 constitute a strained feature 240. In some embodiments, the strained feature 240 has a height of about 30-150 nm. In some embodiments, each strained feature 240 has a diamond-like shape having a turning point at a sidewall thereof, and two adjacent strained features 240 are separated from each other. The strained features are referred to “source/drain regions” in some examples. Source/drain region(s) may refer to a source or a drain, individually or collectively dependent upon the context. In some embodiments, the strained features 240 are used to strain or stress the second nanosheets (which may be referred to as channel nanosheets) 216 and the fins 203. In some embodiments, the strained features 240 include source regions disposed at one side of the dummy gate stack 224 and drain regions disposed at another side of the dummy gate stack 224. The source regions cover ends of the fins 203, and the drain regions cover opposite ends of the fins 203. The strained features 240 are abutted and electrically connected to the second nanosheets 216, while the strained features 240 are electrically isolated from the first nanosheets 214 by the inner spacers 238.

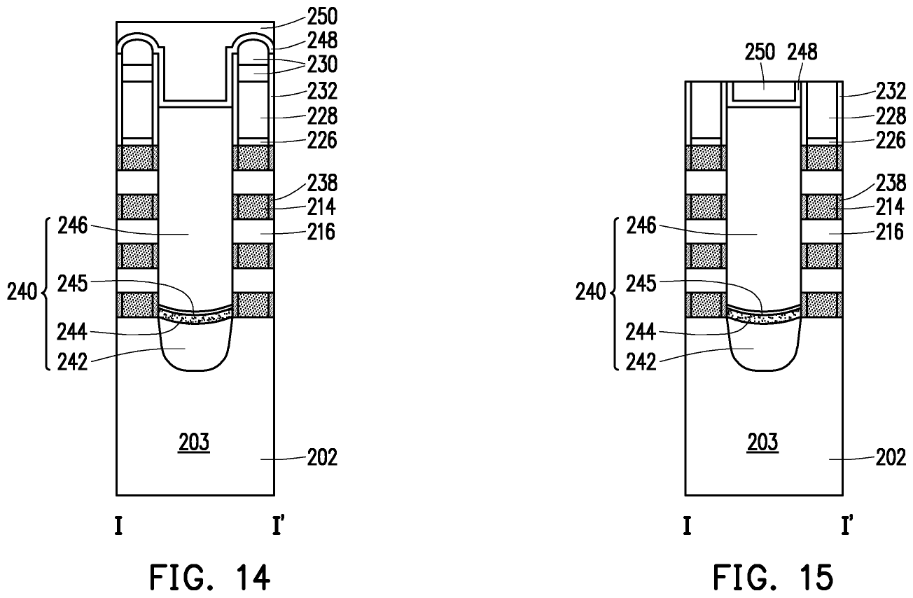

Referring to FIG. 14, a contact etch stop layer (CESL) 248 is formed over the epitaxial layers 246. In some embodiments, the CESL 248 conformally covers the sidewalls of the epitaxial layers 246, and the sidewalls of the spacers 232 and 233. The CESL 248 may include silicon nitride, silicon oxynitride, silicon nitride with oxygen (O) or carbon (C) elements, metal oxide such as Al₂O₃, the like, or a combination thereof, and may be formed by CVD, PVD, ALD, or a suitable process.

Thereafter, an interlayer dielectric (ILD) layer 250 is formed over the CESL 248. In some embodiments, the ILD layer 250 includes silicon oxide, silicon nitride, silicon oxynitride, phosphosilicate glass (PSG), borophosphosilicate glass (BPSG), spin-on glass (SOG), fluorinated silica glass (FSG), carbon doped silicon oxide (e.g., SiCOH), polyimide, the like, or a combination thereof. Other materials such as a low-k material may be applicable. The low-k material has a dielectric constant less than 3.9, less than 3, less than 2.5, or even less. In other embodiments, the ILD layer 250 may have a single-layer structure or a multi-layer structure. In some embodiments, the ILD layer 250 is formed by CVD, PVD, ALD, or a suitable process.

Referring to FIG. 15, a planarization process such as CMP is performed to planarize the topography of the structure. In some embodiments, the ILD layer 250, the CESL 248, the spacers 232 are partially removed and the mask layer 230 is entirely removed, until the top surface of the dummy gate electrode layer 228 is exposed. In some embodiments, the top surface of the dummy gate electrode layer 228 is substantially flushed with the top surfaces of the ILD layer 250, the CESL 248 and the spacers 232.

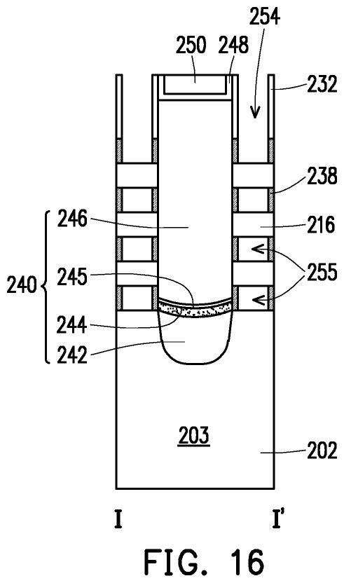

Referring to FIG. 16, the dummy gate stacks 224 (each including a dummy gate electrode layer 228 and a dummy gate dielectric layer 226) are removed to form gate trenches 254. The ILD layer 250 and the CESL 248 protect the strained features 240 during the removal of the dummy gate stacks 224. The dummy gate stacks 224 may be removed using plasma dry etching and/or wet etching. When the dummy gate electrode layer 228 is polysilicon and the ILD layer 250 is silicon oxide, a wet etchant such as a TMAH solution may be used to selectively remove the dummy gate electrode layer. The dummy gate dielectric layer 226 is then removed using plasma dry etching and/or wet etching.

Still referring to FIG. 16, channel nanosheets (or called channel regions) are defined for the GAA device. In some embodiments, an etching process is performed to remove the first nanosheets 214. In some embodiments, the first nanosheets 214 may be completely removed to form gaps 255 between the second nanosheets 216, as shown in FIG. 16. Accordingly, the second nanosheets 216 are separated from each other by the gaps 255. In addition, the bottommost second nanosheet 216 may also be separated from the fin 203 by the gaps 255. As a result, the second nanosheets 216 are suspended. The opposite ends of the suspended second nanosheets 216 are connected to strained features 240. In some embodiments, the suspended second nanosheets 216 may be referred to as “channel nanosheets” or “channel regions”. As shown in FIG. 16, the second nanosheets 216 separated from each and vertically stacked are referred to as a “stack of channel nanosheets” or “stack of semiconductor channels” in some examples.

In some embodiments, a height of the gaps 255 may be about 2 nm to 30 nm. In the present embodiment, the second nanosheets 216 include silicon, and the first nanosheets 214 include silicon germanium. The first nanosheets 214 may be selectively removed by oxidizing the first nanosheets 214 using a suitable oxidizer, such as ozone. Thereafter, the oxidized first nanosheets 214 may be selectively removed from the gate trenches 254. In some embodiments, the etching process includes a dry etching process to selectively remove the first nanosheets 214, for example, by applying an HCl gas at a temperature of about 20° C. to about 300° C., or applying a gas mixture of CF₄, SF₆, and CHF₃.

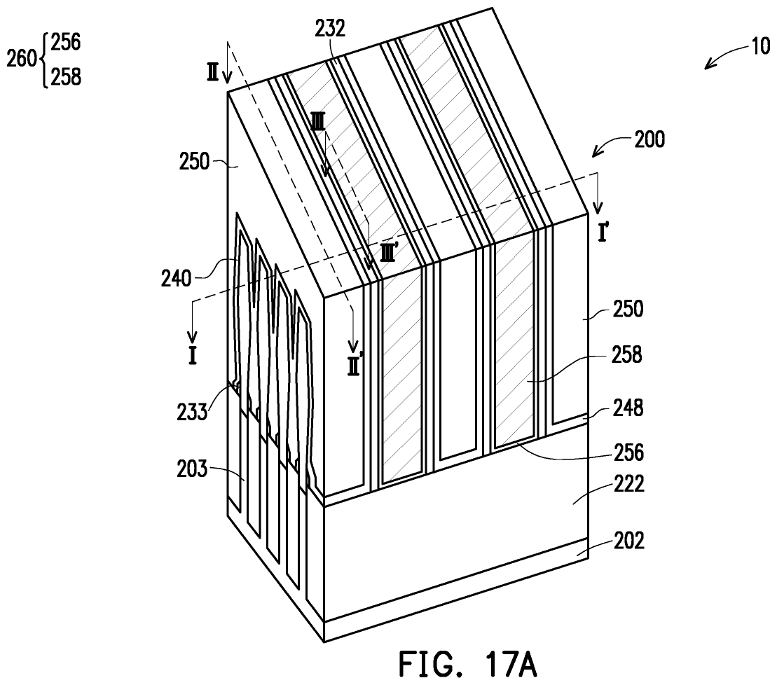

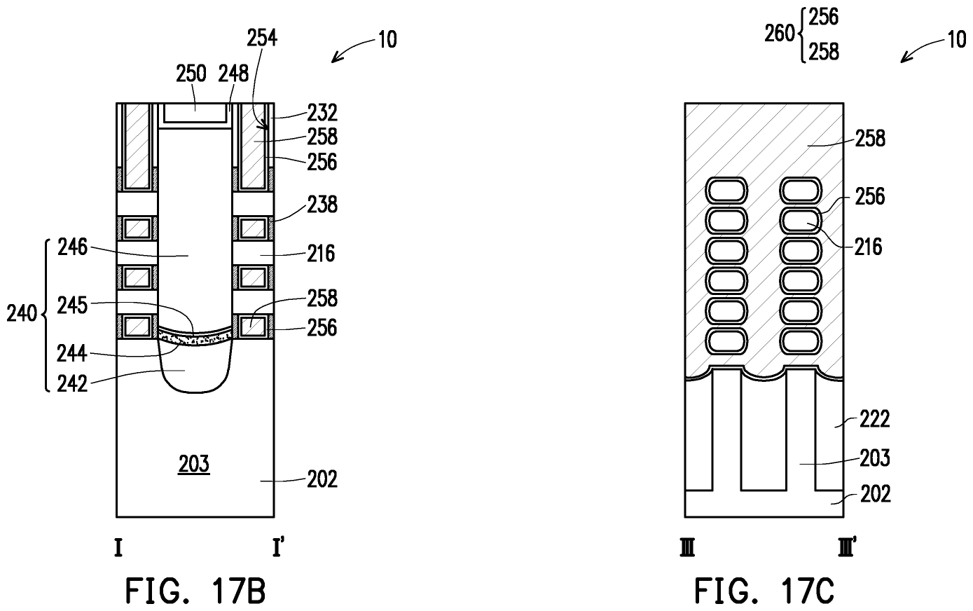

Referring to FIG. 17A, FIG. 17B and FIG. 17C, a gate dielectric layer 256 is formed in the gate trenches 254 and the gaps 255. In some embodiments, the gate dielectric layer 256 conformally covers each gate trench 254 to form a U-shape in cross-section, and further conformally covers the surface of each gap 255 exposed to the gate trenches 254 to form a circle-like shape in cross-section. In some embodiments, the gate dielectric layer 256 includes at least one dielectric material, such as a high-k material. Examples of the high-k material include metal oxide, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, the like, or combinations thereof. The high-k material has a dielectric constant more than 8, more than 15, more than 20, or even more. The gate dielectric layer 256 may be formed by CVD, ALD or a suitable method. In one embodiment, the gate dielectric layer 256 is formed by using a highly conformal deposition process, such as ALD in order to ensure the formation of a gate dielectric layer having a uniform thickness around each channel member. The thickness of the gate dielectric layer 256 is in a range from about 0.5 nm to about 3 nm in some embodiments.

In some embodiments, the gate dielectric layer 256 includes an interfacial layer (not shown) formed between each channel member and the high-k material. For example, the interfacial layer wraps each of the second nanosheets 216 in the channel regions. The interfacial layer may be deposited or thermally grown respectively on the second nanosheets 216 according to acceptable techniques, and made of, for example, silicon oxide, a low-k dielectric material (e.g., a material having a dielectric constant lower the silicon dioxide), silicon oxynitride, the like, or a combination thereof. The thickness of the interfacial layer is in a range from about 0.7 nm to about 2.5 nm in some embodiments.

Thereafter, a gate electrode 258 is formed on the gate dielectric layer 256 to surround each of the second nanosheets 216. In some embodiments, the gate electrode 258 completely fills the gate trenches 254 and the gaps 255. In some embodiments, the gate electrode 258 may include one or more conductive materials, such as polysilicon, aluminum, copper, titanium, tantalum, tungsten, cobalt, molybdenum, tantalum nitride, nickel silicide, cobalt silicide, TIN, WN, TiAl, TiAlN, TaCN, TaC, TaSiN, metal alloy, a suitable material, or a combination thereof. The gate electrode 258 may be formed by CVD, ALD, electro-plating, or other suitable method. The gate dielectric layer 256 and the gate electrode 258 may also be deposited over the upper surfaces of the ILD layer 250 and the CESL 248. The gate dielectric layer 256 and the gate electrode 258 formed over the ILD layer 250 and the CESL 248 are then planarized by using, for example, CMP, until the top surfaces of the ILD layer 250 and the CESL 248 are revealed. In some embodiments, after the planarization operation, the gate electrode 258 is recessed and a cap insulating layer (not shown) is formed over the recessed gate electrode 258. The cap insulating layer includes one or more layers of a silicon nitride-based material, such as

SiN. The cap insulating layer may be formed by depositing an insulating material followed by a planarization operation.

In other embodiments, at least one work function adjustment layer (not shown) is interposed between the gate dielectric layer 256 and the gate electrode 258. The work function adjustment layer is made of a conductive material, such as a single layer of TiN, TaN, TaAlC, TiC, TaC, Co, Al, TiAl, HfTi, TiSi, TaSi or TiAlC, or a multi-layer structure of two or more of these materials. For an N-type device, one or more of TaN, TaAlC, TiN, TiC, Co, TiAl, HfTi, TiSi and TaSi is used as the work function adjustment layer, and for a P-type device, one or more of TiAlC, Al, TiAl, TaN, TaAlC, TIN, TiC and Co is used as the work function adjustment layer. The work function adjustment layer may be formed by ALD, PVD, CVD, e-beam evaporation, or other suitable process. Further, the work function adjustment layer may be formed separately for the N-type device and the P-type device which may use different metal layers.

In some embodiments, the gate electrode 258 and the gate dielectric layer 256 constitute a gate structure 260. Upon the formation of the gate structure 260, a semiconductor device 10 of the embodiment is thus completed. With the method of the disclosure, void-free strained features are obtained by implanting seed layers before epitaxially growing epitaxial layers. Therefore, the device performance is improved and the device reliability is accordingly enhanced.

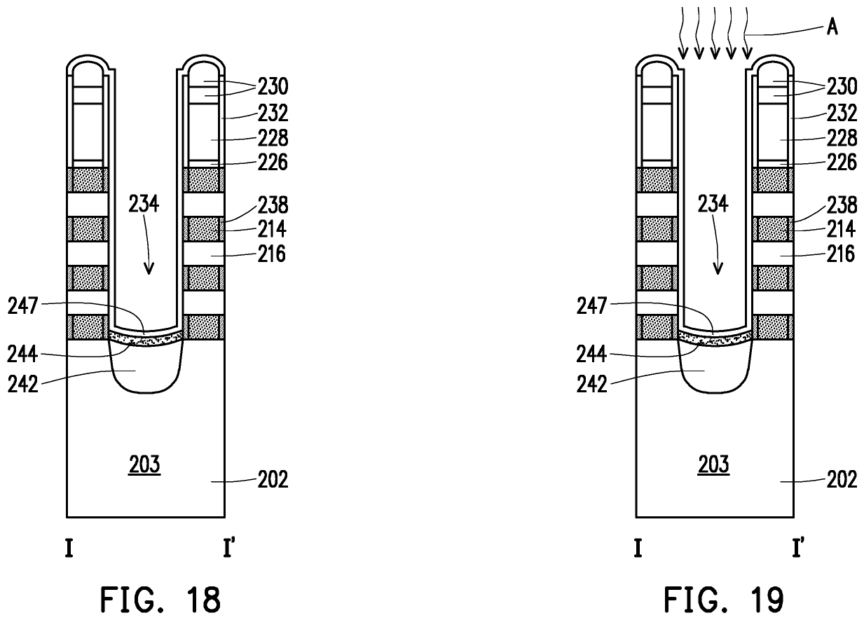

The above embodiments in which the seed layers are formed by an implantation process are provided for illustration purposes, and are not construed as limiting the present disclosure. In other embodiment, the seed layers of the disclosure may be formed by a deposition process, as shown in FIG. 18 to FIG. 21.

First, operations similar to those of FIG. 1 to FIG. 9B are performed, so as to provide an intermediate structure of FIG. 10. As shown in FIG. 10, a recess 234 is formed in the substrate 202, a liner layer 242 is formed in the bottom of the recess 234, and an insulating layer 244 is formed in the recess 234 over the liner layer 242. The element configurations, materials and forming methods of the liner layer 242, the insulating layer 244 and adjacent elements are the same those described above, so the details are not iterated herein.

Referring to FIG. 18, a seed layer 247 is conformally formed over the substrate 202, covering the sidewall and bottom of the recess 234. In some embodiments, the seed layer 247 includes amorphous silicon, polysilicon, crystalline silicon, amorphous germanium, polycrystalline germanium, crystalline germanium, the like or a combination thereof. In some embodiments, the seed layer is formed by CVD, PECVD, ALD, PECVD, furnace, sputtering, pulse laser deposition (PLD), the like or a suitable process. In some embodiments, a dopant species is introduced to the chamber during the deposition of the seed layer 247 (e.g., in-situ phosphorous or boron doping CVD or ALD), which has a conductivity type the same as that of the subsequently formed epitaxial layer. For example, the dopant species includes B, P As, C, Ge or a combination thereof, and the dopant concentration ranges from about 1E20 to 1E22 atom/cm³. In some embodiments, the insulting layer 244 has a thickness of about 3-20 nm, and the seed layer 247 formed by a depositing process has a thickness of about 0.5-10 nm or about 1-5 nm.

Referring to FIG. 19, an annealing process A is performed to the seed layer 247. In some embodiments, the annealing process A is performed at a temperature from about 300° C. to 1200° C. for about 10⁻³ to 10³ seconds. The annealing process A is referred to as a “post-annealing process” in some examples. The annealing process A is performed to transform an amorphous seed layer 247 into a mixed crystalline-amorphous seed layer 247 or a fully crystalline seed layer 247. The annealing process A is optional and may be omitted in some examples. For example, when the seed layer 247 is a polysilicon layer or a polycrystalline germanium layer, an annealing process may not be required.

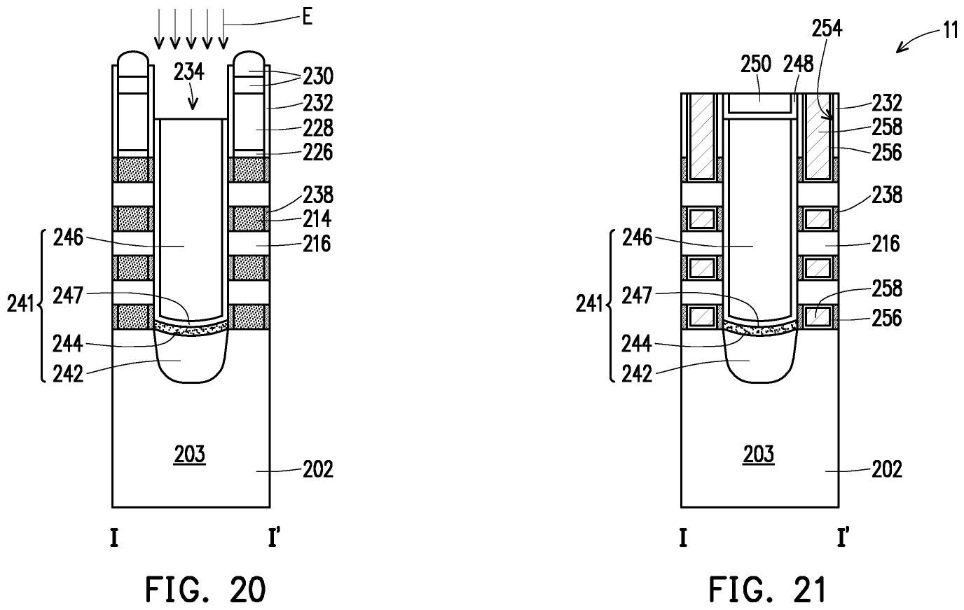

Referring to FIG. 20, an epitaxial layer 246 is epitaxially grown in the recess 234 from the seed layer 247. In some embodiments, the seed layer 247 is beneficial for forming the epitaxial layer 246 in the recess 234, because the seed layer 247 provides a better interface than the insulating layer 244 for epitaxially growing the epitaxial layer 246. Therefore, the epitaxial layer 246 is a void-free or seam-free epitaxial feature. In some embodiments, the epitaxial layer 246 includes SiP, SiAs, SiSb, SiP+SiAs, SiP+SiSb, SiP+SiAs+SiSb or the like, each of which may be doped with C, for an N-type device. In some embodiments, the epitaxial layer 246 includes Si: B, Si: Ga, Si: In, SiGe, SiGe: B, SiGe: Ga, SiGe: In or the like, for a P-type device. In some embodiments, when the epitaxial layer 246 is provided for an N-type device, the seed layer 247 may include amorphous silicon, polysilicon and/or crystalline silicon, optionally doped with an N-type dopant. In some embodiments, when the epitaxial layer 246 is provided for a P-type device, the seed layer 247 may include amorphous germanium, polycrystalline germanium and/or crystalline germanium, optionally doped with a P-type dopant. In some embodiments, the P-type or N-type dopant concentration ranges from about 1E20 to 1E22 atom/cm³.

In this embodiment, the seed layer 247 is formed on the sidewall and bottom of the recess 234, so the epitaxial material is epitaxially grown from the seed layer 247 on the sidewall and bottom of the recess 234, and is finally merged to a void-free or seam-free epitaxial feature. Such seed layer 247 may facilitate the formation of the epitaxial layer 246

In some embodiments, an etching process E is optionally performed to remove the excess portions of the seed layer 247 and the epitaxial layer 246, until the remaining the seed layer 247 and the epitaxial layer 246 have the desired height. The etching process may include a dry etching, a wet etching or a combination thereof. In some embodiments, a liner layer 242, an insulating layer 244, a seed layer 247 and an epitaxial layer 246 in each recess 234 constitute a strained feature 241. In some embodiments, the strained feature 241 has a height of about 30-150 nm. In some embodiments, each strained feature 241 has a diamond-like shape having a turning point at a sidewall thereof, and two adjacent strained features 241 are separated from each other

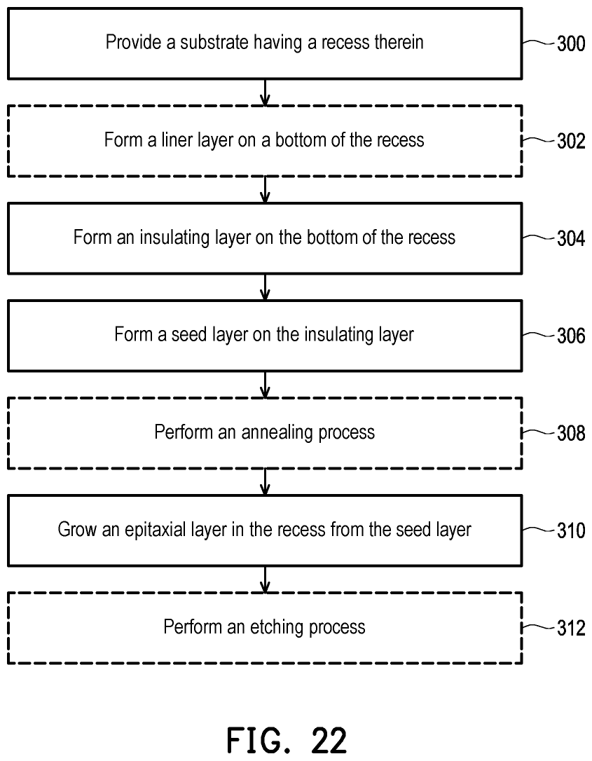

Referring to FIG. 21, operations similar to those of FIG. 14 to FIG. 17C are performed, so as to provide a semiconductor device 11. With the method of the disclosure, void-free strained features are obtained by depositing seed layers before epitaxially growing epitaxial layers. Therefore, the device performance is improved and the device reliability is accordingly enhanced.

FIG. 22 illustrates a flow chart of a method of forming a semiconductor device in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 300, a substrate is formed with a recess therein. In some embodiments, the substrate has a gate stack thereon, and the recess is formed in the substrate adjacent to the gate stack. In some embodiments, the gate stack is a GAA structure. In other embodiments, the gate stack is a FinFET structure or a planar transistor structure. FIG. 1 to FIG. 9B illustrate different views corresponding to some embodiments of act 300.

At act 302, a liner layer is formed on a bottom of the recess. In some embodiments, the liner layer includes Si, Ge or SiGe. FIG. 10 illustrates a cross-sectional view corresponding to some embodiments of act 302. Act 302 is optional and may be omitted as needed.

At act 304, an insulating layer is formed on the bottom of the recess. In some embodiments, the insulating layer includes silicon oxide, silicon nitride, SiON, SiC, SiCN, SiOCN, metal oxide, metal nitride or a combination thereof. FIG. 10 illustrates a cross-sectional view corresponding to some embodiments of act 304. In some embodiments, the insulating layer is in physical contact with the substrate when act 302 is omitted.

At act 306, a seed layer is formed on the insulating layer. In some embodiments, the seed layer is in physical contact with the insulating layer.

In some embodiments, the seed layer is formed by performing an implantation process to a surface portion of the insulating layer. In some embodiments, an implanted species of the implantation process includes Si, SiFₓ, Ge, GeFₓ or a combination thereof, and an implanted concentration of the implantation process ranges from about 1E21 to 1E23 atom/cm⁻³. In some embodiments, the implanted species of the implantation process further includes a dopant the same as that of the epitaxial layer, and a dopant concentration of the implantation process ranges from about 1E20 to 1E22 atom/cm⁻³. In some embodiments, an implanted temperature of the implantation process ranges from about −100° C. to 500° C. FIG. 11 illustrates a cross-sectional view corresponding to some embodiments of act 306.

In other embodiments, the seed layer is formed by performing a depositing process. In other embodiments, the seed layer includes amorphous silicon, polysilicon, crystalline silicon, amorphous germanium, polycrystalline germanium, crystalline germanium, or a combination thereof. FIG. 18 illustrates a cross-sectional view corresponding to some embodiments of act 306.

At act 308, an annealing process is performed to the seed layer. FIG. 12 and FIG. 19 illustrate cross-sectional views corresponding to some embodiments of act 308. Act 308 is optional and may be omitted as needed.

At act 308, an epitaxial layer is grown in the recess from the seed layer. FIG. 13A, FIG. 13B and FIG. 20 illustrate different views corresponding to some embodiments of act 308.

At act 310, an etching process is performed. FIG. 20 illustrates a cross-sectional view corresponding to some embodiments of act 310. Act 310 is optional and may be omitted as needed.

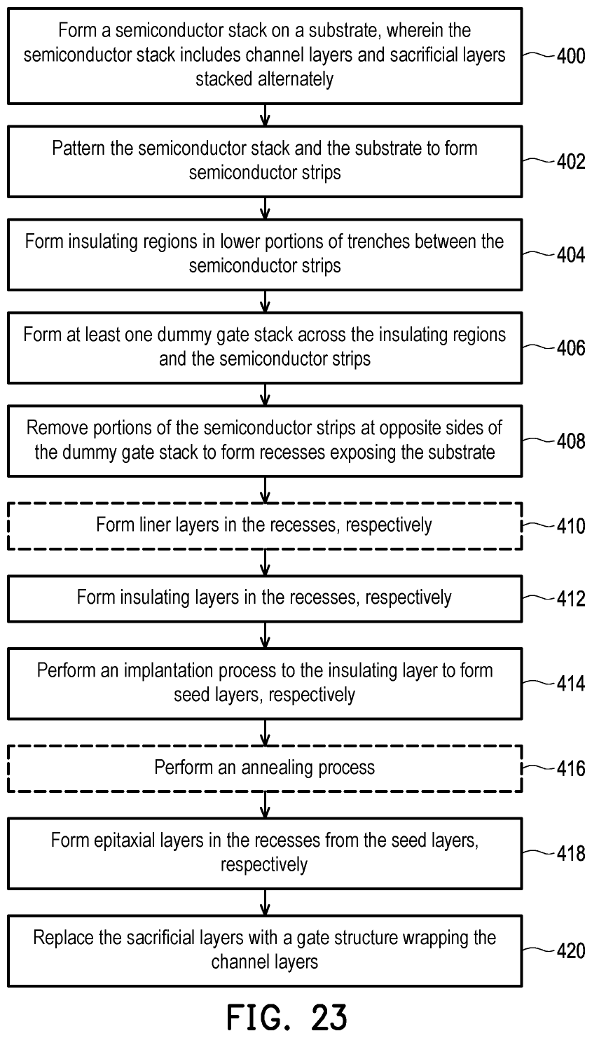

FIG. 23 illustrate a flow chart of a method of forming a semiconductor device in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 400, a semiconductor stack is formed on a substrate, wherein the semiconductor stack includes channel layers and sacrificial layers stacked alternately. FIG. 1 illustrates a perspective view corresponding to some embodiments of act 400.

At act 402, the semiconductor stack and the substrate are patterned to form semiconductor strips. FIG. 1 and FIG. 2 illustrate perspective views corresponding to some embodiments of act 402.

At act 404, insulating regions are formed in lower portions of trenches between the semiconductor strips. FIG. 3 and FIG. 4 illustrate perspective views corresponding to some embodiments of act 404.

At act 406, at least one dummy gate stack is formed across the insulating regions and the semiconductor strips. FIG. 5 illustrates a perspective view corresponding to some embodiments of act 406.

At act 408, portions of the semiconductor strips at opposite sides of the dummy gate stack are removed to form recesses exposing the substrate. FIG. 6A, FIG. 6B. FIG. 7A and FIG. 7B illustrate different views corresponding to some embodiments of act 408.

At act 410, liner layers are formed in the recesses, respectively. FIG. 10 illustrates a cross-sectional view corresponding to some embodiments of act 410. Act 410 is optional and may be omitted as needed.

At act 412, insulating layers are formed in the recesses, respectively. FIG. 10 illustrates a cross-sectional view corresponding to some embodiments of act 412. In some embodiments, the insulating layers are in physical contact with the substrate when act 410 is omitted.

At act 414, an implantation process is performed to the insulating layers to form seed layers, respectively. In some embodiments, an implanted species of the implantation process includes Si, SiFₓ, Ge, GeFₓ or a combination thereof, and an implanted concentration of the implantation process ranges from about 1E21 to 1E23 atom/cm⁻³. In some embodiments, the implanted species of the implantation process further includes a dopant the same as that of the epitaxial layer, and a dopant concentration of the implantation process ranges from about 1E20 to 1E22 atom/cm⁻³. FIG. 11 illustrates a cross-sectional view corresponding to some embodiments of act 414.

At act 416, an annealing process is performed. FIG. 12 and FIG. 19 illustrate cross-sectional views corresponding to some embodiments of act 416. Act 416 is optional and may be omitted as needed.

At act 418, epitaxial layers are formed in the recesses from the seed layers, respectively. FIG. 13A, FIG. 13B and FIG. 20 illustrate different views corresponding to some embodiments of act 418.

At act 420, the sacrificial layers are replaced with a gate structure wrapping the channel layers. FIGS. 14-17C and FIG. 21 illustrate different views corresponding to some embodiments of act 420.

The structures of the semiconductor devices are illustrated below with reference to FIG. 17A, FIG. 17B, FIG. 17C and FIG. 21.

A semiconductor device 10/11 includes a stack of channel nanosheets 216 disposed on a substrate 202, a gate structure 260 wrapping the stack of channel nanosheets 216, and a strained feature 240/241 disposed in the substrate 202 adjacent to the stack of channel nanosheets 216. In some embodiments, the strained feature 240/241 includes, from bottom to top, an insulating layer 244, a seed layer 245/247 and an epitaxial layer 246.

In some embodiments, the seed layer 245 the has a horizontal I-shape in cross-section. The horizontal I-shape may include a curved horizontal I-shape, a recessed horizontal I-shape, or straight horizontal I-shape. In other embodiments, the seed layer 247 has a U-shape in cross-section. In some embodiments, the seed layer includes Si or Ge. In some embodiments, the seed layer the seed layer has a gradient silicon or germanium concentration.

In some embodiments, the semiconductor device 10/11 further includes a liner layer 242 disposed between the substrate 202 and the insulating layer 244, wherein the liner layer 242 includes Si, Ge or SiGe. In some embodiments, the insulating layer 244 is in physical contact with the liner layer 242 and the seed layer 245/247.

In view of above, in some embodiments of the disclosure, a seed layer is formed on top of an insulating layer in each source/drain recess, and an epitaxial layer is then grown by using the seed layer as a seed. The seed layer provides a good interface for epitaxially growing the epitaxial layer. Therefore, the epitaxial layer is formed without a seam or void, and the device performance and device reliability are accordingly improved.

According to some embodiments, a method of forming a semiconductor device includes: providing a substrate having a recess therein; forming an insulating layer on a bottom of the recess; forming a seed layer on the insulating layer; and growing an epitaxial layer in the recess from the seed layer.

According to some embodiments, a method of forming a semiconductor device includes: forming a semiconductor stack on a substrate, wherein the semiconductor stack includes channel layers and sacrificial layers stacked alternately; patterning the semiconductor stack and the substrate to form semiconductor strips; forming insulating regions in lower portions of trenches between the semiconductor strips; forming at least one dummy gate stack across the insulating regions and the semiconductor strips; removing portions of the semiconductor strips at opposite sides of the dummy gate stack to form recesses exposing the substrate; forming insulating layers in the recesses, respectively; performing an implantation process or a deposition process to the insulating layers to form seed layers, respectively; and forming epitaxial layers in the recesses from the seed layers, respectively.

According to some embodiments, a semiconductor device includes: a stack of channel nanosheets disposed on a substrate; a gate structure wrapping the stack of channel nanosheets; and a strained feature disposed in the substrate adjacent to the stack of channel nanosheets. The strained feature includes, from bottom to top, an insulating layer, a seed layer and an epitaxial layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, comprising:
providing a substrate having a recess therein;
forming an insulating layer on a bottom of the recess;
forming a seed layer on the insulating layer; and
growing an epitaxial layer in the recess from the seed layer.

2. The method of claim 1, wherein the seed layer is formed by performing an implantation process to a surface portion of the insulating layer.

3. The method of claim 2, wherein an implanted species of the implantation process comprises Si, SiFₓ, Ge, GeFₓ or a combination thereof.

4. The method of claim 2, wherein an implanted concentration of the implantation process ranges from about 1E21 to 1E23 atom/cm⁻³.

5. The method of claim 2, wherein an implanted temperature of the implantation process ranges from about −100° C. to 500° C.

6. The method of claim 2, further comprising performing an annealing process after the implantation process.

7. The method of claim 1, wherein the seed layer is formed by performing a depositing process.

8. The method of claim 7, wherein the seed layer comprises amorphous silicon, polysilicon, crystalline silicon, amorphous germanium, polycrystalline germanium, crystalline germanium, or a combination thereof.

9. The method of claim 1, further comprising forming a liner layer between the substrate and the insulating layer, wherein the liner layer comprises Si, Ge or SiGe.

10. A method of forming a semiconductor device, comprising:
forming a semiconductor stack on a substrate, wherein the semiconductor stack comprises channel layers and sacrificial layers stacked alternately;
patterning the semiconductor stack and the substrate to form semiconductor strips;
forming insulating regions in lower portions of trenches between the semiconductor strips;
forming at least one dummy gate stack across the insulating regions and the semiconductor strips;
removing portions of the semiconductor strips at opposite sides of the dummy gate stack to form recesses exposing the substrate;
forming insulating layers in the recesses, respectively;
performing an implantation process or a deposition process to the insulating layers to form seed layers, respectively; and
forming epitaxial layers in the recesses from the seed layers, respectively.

11. The method of claim 10, wherein an implanted species of the implantation process comprises Si, SiFₓ, Ge, GeFₓ or a combination thereof.

12. The method of claim 11, wherein an implanted concentration of the implantation process ranges from about 1E21 to 1E23 atom/cm⁻³.

13. The method of claim 11, wherein the implanted species of the implantation process further comprises a dopant the same as that of the epitaxial layer.

14. The method of claim 10, wherein each of the seed layers has a gradient silicon or germanium concentration.

15. The method of claim 10, further comprising performing an annealing process after the implantation process and before forming the epitaxial layer.

16. A semiconductor device, comprising:
a stack of channel nanosheets disposed on a substrate
a gate structure wrapping the stack of channel nanosheets; and
a strained feature disposed in the substrate adjacent to the stack of channel nanosheets,
wherein the strained feature comprises, from bottom to top, an insulating layer, a seed layer and an epitaxial layer.

17. The semiconductor device of claim 16, wherein the seed layer has a gradient silicon or germanium concentration.

18. The semiconductor device of claim 16, further comprising a liner layer disposed between the substrate and the insulating layer, wherein the liner layer comprises Si, Ge or SiGe.

19. The semiconductor device of claim 16, wherein the seed layer has a horizontal I-shape in cross-section.

20. The semiconductor device of claim 16, wherein the seed layer has a U-shape in cross-section.
